(19) United States
(12) Patent Application Publication
(10) Pub. No.: US 2006/0220129 A1
(43) Pub. Date: Oct. 5, 2006

(54) Hybrid fully SOI-type multilayer structure

(76) Inventors: Fabrice Letertre, Grenoble (FR); Carlos Mazure, Bernin (FR)

Correspondence Address: WINSTON & STRAWN LLP, 1700 K STREET, N.W., WASHINGTON, DC, 20006, US

(21) Appl. No.: 11/342,380

(22) Filed: Jan. 27, 2006

Related U.S. Application Data
(63) Continuation of application No. PCT/IB05/01136, filed on Mar. 29, 2005.

(51) Int. Cl. H01L 27/12

(52) U.S. Cl. 257/347

(57) ABSTRACT

The invention relates to a silicon-on-insulator-type multilayer structure that includes a support layer, at least two working layers having different crystalline orientations, and an insulating layer extending over at least a portion of the support layer. This insulating layer extends over the whole surface of the support layer so as to extend completely between the support layer and the working layers. A process for manufacturing such a structure is also provided.

### CROSS-REFERENCE TO RELATED APPLICATIONS

This application is a continuation of International application PCT/IB2005/001136 filed Mar. 29, 2005, the entire content of which is expressly incorporated herein by reference thereto.

### BACKGROUND

The invention concerns a silicon-on-insulator (“SOI”)-type multilayer structure. This type structure is one that includes a support layer, at least one working layer and an electrically insulating layer between the working layer(s) and the support layer. More specifically, the invention concerns a SOI-type multilayer structure comprising at least two working layers having different crystalline orientations. Also, the invention concerns a process for manufacturing such structures.

An advantageous application of these structures is the design and manufacturing of high performance CMOS circuits. As an example, such high performance includes boosting the speed of NMOS and PMOS transistor devices for a given power consumption. This allows the building of very complex circuits, such as million gate logic ones, whose performance in term of speed are very high without consuming too much power. These kinds of circuits are usually known as LVLP circuits (Low Voltage Low Power).

Several approaches have been proposed in order to make such circuits. A first approach consists in downscaling the channel size of the transistor devices. This approach has been widely used for many years and has demonstrated its effectiveness. Until now, the channel length of the transistor devices has been scalable on a path following Moore's law. As the length becomes increasingly small, it becomes increasingly difficult to keep the pace of this law. Indeed, today the industry encounters many difficulties notably because it is approaching the fundamental physical limits of CMOS scaling. Moreover, the apparatuses needed for the transistor fabrication process must push away the limits of accuracy. Consequently, even if this approach remains attractive, the potential of performance improvements is limited today and alternative approaches have been investigated.

Another well known approach uses strained semiconductor substrates. Indeed strained silicon technologies provide high electron mobility which translates into a performance enhancement of 20% to 30% for the NMOS transistor devices. However, in this approach a particular attention must be brought to the electron to hole mobility ratio. Indeed, when processing a classical non-strained bulk substrate for making CMOS circuits, this ratio is in the order of three, which means that the holes mobility is three times lower than the mobility of electrons, indicating thereby that a NMOS transistor device is usually three times faster than a PMOS transistor device.

Circuit designers are used to manage such ratio of the order of three. They compensate this mobility imbalance by increasing the PMOS transistor width to length ratio when combining NMOS and PMOS transistors. Consequently, for a fixed length value, the width and then the sizes of the PMOS transistor devices is increased. Such compensation corresponds to limitations in term of area and overall circuit performance. For example, increasing the width to length ratio increases the capacitances of the device which often penalizes the speed to power consumption ratio of the circuit (this is indeed the case when one electrical node connected to the PMOS device has critical effects on the transfer function of the circuit).

And in the case of strained silicon, the increase of electron mobility further increases the above mentioned ratio. Therefore, despite the advantages associated to enhancing by 20% to 30% the electron mobility, strained silicon technology is associated to a high electron to hole mobility ratio and is exposed to the above mentioned limitations.

Another known solution consists of realizing PMOS and NMOS transistor devices with respective working layers having respectively a (1,1,0) and a (1,0,0) crystalline orientation. It is indeed well-known that PMOS transistor devices exhibit better performance in a (1,1,0) crystal because their carriers mobility (the holes mobility) is enhanced. As an example, in such a crystal, the holes mobility can be increased by a factor of 2.5 with respect to the one obtained in a (1,0,0) crystal. Therefore, combining (e.g. in SOI structure) a first (1,0,0) semiconductor working layer with a second (1,1,0) semiconductor working layer in the same CMOS technology allows improving the mobility of both the NMOS and the PMOS transistor devices.

In this regard, such a SOI structure with a surface pattern based on two working layers, made respectively of a (1,0,0) and a (1,1,0) silicon has yet been proposed (see, e.g., M. Yang, et al., High Performance CMOS Fabricated on Hybrid Substrate With Different Crystal Orientations, IEDM 2003, IEEE, and B. Doris et al., A simplified Hybrid Orientation Technology (SHOT) for High Performance CMOS, Dig. of Tech. Papers in Symposium on VLSI Technology, IEEE 2004). In the present specification, reference in this text to a “hybrid” structure is intended to include semiconductor multilayer structures having at least two working layers, made of respective semiconductor materials having different crystalline orientations.

FIGS. 1a to 1d illustrates an example of a manufacturing process for such a hybrid structure which has been proposed. The process begins on an intermediate structure S1 comprising a semiconductor working layer 10 placed on top of an insulator layer 11, the insulator layer covering a support semiconductor layer 20. Layers 10 and 20 are typically made of silicon. This intermediate structure is thus of the SOI type. The working layer 10 and the support layer 20 have different crystal orientations. For example, the working layer 10 can have a (1,0,0) crystal orientation, and the support layer 20 can have a (1,1,0) crystal orientation.

FIG. 1b further illustrates the removal of a portion of layers 10 and 11, in order to have a direct access to the corresponding portion of layer 20, through a free space 13. As illustrated in FIGS. 1c and 1d, the free space 13 thus created above layer 20 can be first partially filled with a vertical insulator 12, and then the remaining free space is filled with the same material as the material of layer 20, e.g. by epitaxial regrowth on support layer 20. The layer of material thus created above the support layer forms an additional working layer 21 in the structure. This additional working layer is isolated from working layer 10 by the vertical insulator 12.

A hybrid multilayer structure S is thus created with two different working layers 10 and 21 having different crystal orientations. In such a hybrid structure, NMOS transistor devices can be directly realized in the working layer 10. Correspondingly, PMOS transistor devices can be directly built in the working layer 21. However, such a hybrid substrate is associated with at least a major limitation: if the NMOS devices which will be built in working layer 10 shall be of the SOI type (since an insulating layer lies between layer 10 and the support 20), this shall not be the case concerning the PMOS devices made on layer 21. Indeed, the layer 21 is directly in contact with the support layer 20, from which it is therefore not isolated. And the PMOS transistor devices that will be built in this working layer shall therefore be “bulk type” transistors. Thus, such a structure is only capable to provide SOI NMOS transistor devices having a crystalline orientation (1,0,0) and bulk type PMOS transistor devices whose crystal orientation is (1,1,0).

The present invention has been made in order to overcome the disadvantages of the prior art structure and manufacturing procedures.

### SUMMARY OF THE INVENTION

The present invention now provides a complete SOI hybrid structure, i.e., one capable of providing both a (1,0,0) NMOS SOI transistor and a (1,1,0) PMOS SOI transistor. This combines the full performance of an SOI substrate with the use of hybrid crystalline orientation structures. More generally, the invention provides silicon-on-insulator-type of multilayer structure having a support layer, an insulating layer, and at least two working layers corresponding to two different crystalline orientations, with the working layers electrically isolated from the support layer of the structure by the insulating layer.

The multilayer structure can further comprise a plurality of different stacking areas, with each stacking area comprising a first composition of a support layer, an insulator layer; and a first working layer having an exposed top surface, or second composition of a support layer, an insulator layer; a first working layer and a second working layer having an exposed top surface, so that within each stacking area either the first or second working layer has an exposed top surface. Advantageously, the first working layer has a thickness in the first composition that is equal to the total thickness of the first and second working layers of the second composition so that the structure has a uniform top surface. Preferably, the working layers of one stacking area are electrically isolated from the working layers of adjacent stacking areas.

The invention also relates to a process for manufacturing a silicon-on-insulator-type multilayer structure that includes a support layer, at least two working layers having different crystalline orientations, and an insulating layer for electrically isolating the support layer from the working layers, which method comprises providing an intermediate structure that includes the support layer, the insulating layer and a first working layer having an exposed surface; and subsequently associating the second working layer upon the exposed surface of the first working layer of the intermediate structure to form the silicon-on-insulator-type multilayer structure.

The process preferably comprises forming the intermediate structure by providing the insulating layer upon the support layer, implanting atomic species in a first source substrate to form an embrittlement zone which defines within the first source substrate a layer corresponding to the first working layer, bonding the first source substrate to the insulating layer; and splitting the first source substrate at the embrittlement zone so that the first working layer is transferred to the intermediate structure. Subsequently, the second working layer can be provided by implanting species in a second source substrate to form an embrittlement zone which defines within the second source substrate a layer corresponding to the second working layer, bonding the second source substrate to the first working layer, and splitting the second source substrate at the embrittlement zone to transfer the second working layer to the SOI-type multilayer structure.

### BRIEF DESCRIPTION OF THE DRAWING FIGURES

Further advantages of the present invention will become more apparent on reading the following detailed description of a preferred implementation of the invention, this being given by way of non limiting example and with reference to appended drawings in which:

FIG. 1 which has been commented above shows different steps of a prior art manufacturing process of a SOI-type multilayer structure comprising two working layers having different crystalline orientations,

FIG. 2 schematically illustrates main steps of a process of manufacturing a SOI-type multilayer structure according to the invention when starting from an intermediate structure,

FIG. 3 illustrates an example of steps for forming the intermediate structure,

FIG. 4 illustrates in a more detailed manner the steps of the process of manufacturing a SOI-type multilayer structure according to the invention when starting form the intermediate structure,

FIG. 5 shows a SOI-type multilayer structure according to the invention which comprises regions having respective different types of layer stacking,

FIG. 6 shows a SOI-type multilayer structure according to the invention which comprises a trench which can be filled by an insulator,

FIG. 7 shows a SOI-type multilayer structure according to the invention in which two working layers are separated by an insulator.

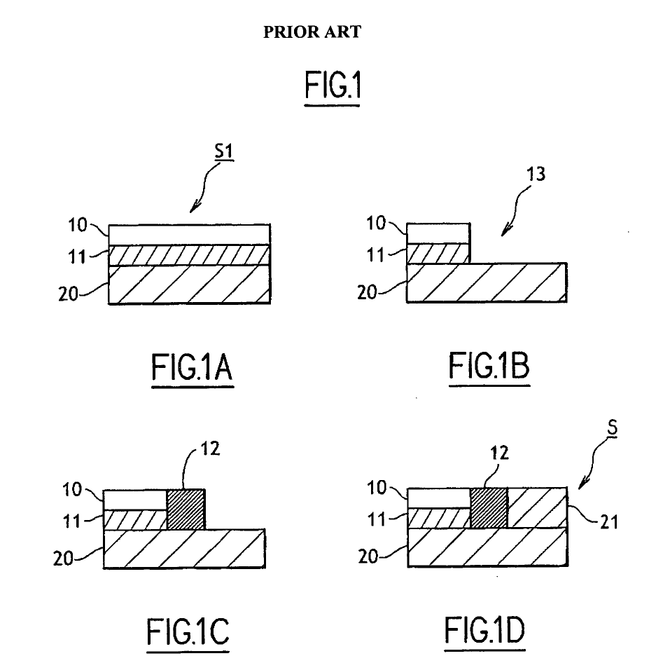

### DETAILED DESCRIPTION OF THE PREFERRED EMBODIMENTS

The invention proposes, according to a first aspect, a SOI-type multilayer structure, comprising a support layer, at least two working layers having different crystalline orientations, and an insulating layer extending over at least a portion of the support layer. Preferably, this insulating layer extends sufficiently over the whole surface of the support layer, so as to extend completely between the support layer and the working layers to provide insulation therebetween.

Preferred aspects of such SOI-type multilayer structure according to the invention include the following:

at least two working layers are superimposed;

the SOI-type multilayer structure may comprise only two working layers;

the working layers are preferably made of silicon;

one working layer is made of a (1,0,0) crystal and another working layer is made of a (1,1,0) crystal, with the working layer made of the (1,0,0) crystal adapted for the manufacturing of NMOS type transistors while the working layer made of the (1,1,0) crystal is adapted for the manufacturing of PMOS type transistors;

the SOI-type multilayer structure advantageously comprises a plurality of different stacking areas, the layer composition of each stacking area being of one of the following types:
a first composition type: support layer—insulator layer—first working layer exposing its top surface,
a second composition type: support layer—insulator layer—first working layer—second working layer exposing its top surface,
   so that within each of the stacking areas one of the first and second working layers has an exposed top surface;

the thickness of the first working layer in the first composition type is equal to the added thicknesses of the first and second working layers in the second composition type so that the top surface of the structure is even;

the working layers of a stacking area are electrically isolated from adjacent working layers of adjacent stacking areas;

electrical isolation is preferably performed by Shallow Trench Isolation;

at least one working layer is mono-crystalline;

at least one working layer is a strained semiconductor;

the strained semiconductor working layer may be tensile or compressive strained;

an additional electrical insulator layer lies between two working layers, so that the working layers are electrically isolated from each other; and

the insulating layer(s) is(are) made of an oxide.

According to a second aspect, the invention provides a process for manufacturing a SOI-type multilayer structure. This process uses a layer transfer technique, and includes the following steps:

forming an intermediate structure including the support layer, a first working layer, and the insulating layer, and

forming on top of the intermediate structure a second working layer having a crystalline orientation which is different from the crystalline orientation of the first working layer.

Preferred aspects of this manufacturing process include the following steps:
forming an intermediate structure by:
   insulating layer above the support layer,
   implanting species in a first source substrate in order to form an embrittlement zone which defines within the first source substrate a layer corresponding to a first working layer of the structure,
   bonding the first source substrate to the insulating layer,
   splitting the first source substrate at the embrittlement zone formed in the first source substrate, so that the portion of the first substrate source which remains bonded to the insulating layer becomes the first working layer of the intermediate structure,
forming on top of the intermediate structure a second working layer by:
   implanting species in a second source substrate in order to form an embrittlement zone which defines within the second source substrate a layer corresponding to a second working layer of the structure,
   bonding the second source substrate to the first working layer,
   splitting the second source substrate at the embrittlement zone formed in the second source substrate, so that the portion of the second substrate source which remains bonded to the first working layer becomes a second working layer of the SOI-type multilayer structure.

an additional step of treating the surface of the intermediate structure before forming on top of the intermediate structure a second working layer;

an additional step of selectively removing desired portions of the second working layer, so that the SOI-type multilayer structure comprises two types of layer stacking:
a first stacking type: support layer—insulator layer—first working layer,
a second stacking type: support layer—insulator layer—first working layer—second working layer.

an additional step of selectively forming desired trenches which expose the insulating layer to the outer environment;

if desired, an additional step of filling the trenches with an electrical insulator or electrical insulating material;

selecting the working layers of the structure as semiconductor layers;

selecting the working layers to be mono-crystalline layers;

selecting one of the working layers to be made of a (1,0,0) crystal and another of the working layers to be made of a (1,1,0) crystal;

providing at least one of the working layers in a strained state, with the strain being

tensile or compressive strain;

an additional step of forming an additional insulating layer between the two working layers before bonding the two working layers together;

providing the insulating layer(s) to be made of an oxide.

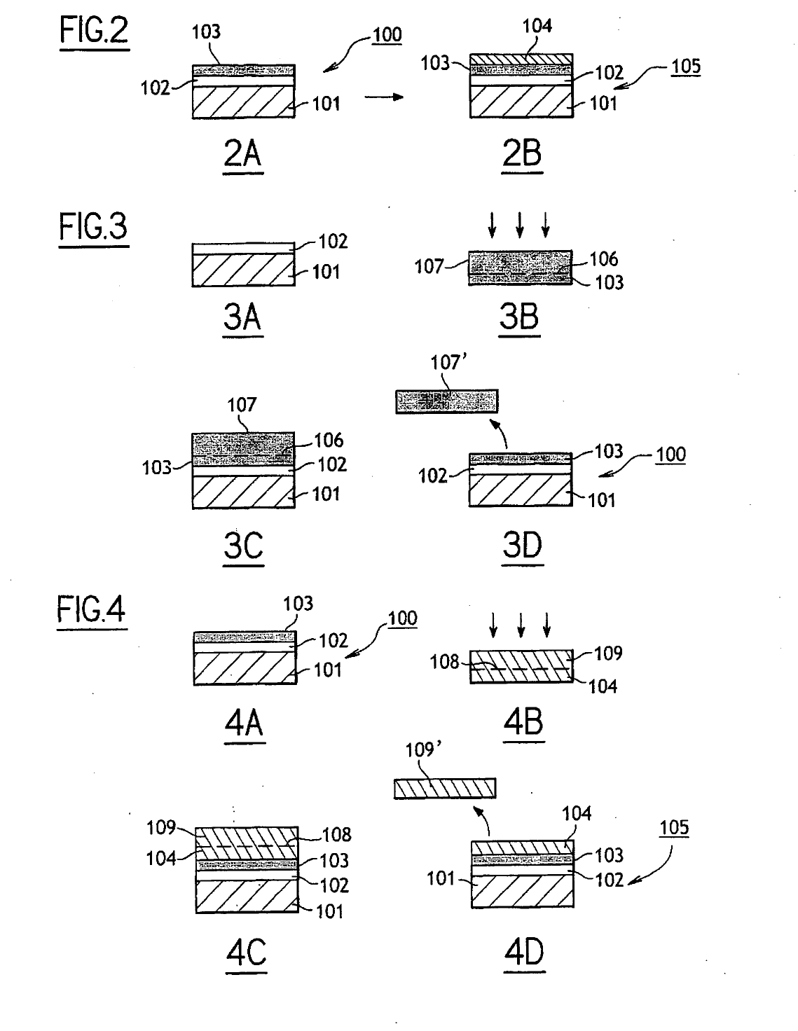

Referring now to FIG. 2, a SOI-type multilayer structure 105 according to the invention is obtained starting from an intermediate structure 100. The intermediate structure 100 comprises a support layer 101 supporting an insulating layer 102. This insulating layer 102 extends between the support layer 101 and a working layer 103. Therefore this intermediate structure comprises a support layer, an insulating layer and a working layer. However, other layers could be formed within such structure, the main idea being that the intermediate structure is at least composed of the three layers mentioned above.

In this regard, one draws the attention that in the invention, a working layer of a SOI-type structure is understood as a layer located above the insulating layer of the structure, and in which a channel of electrical current may be formed. In other words, a working layer may serve as a layer for carrier transport. As a non-limiting example, in a NMOS SOI transistor, a working layer is a layer in which electrons are passing from a source to a drain of the transistor, so as to generate a controlled drain to source current.

Accordingly, there may be situations where the working layer comprises more than one layer. Additionally the material of such layers which form the working layer may be of any type. As a non-limiting example each of these layers may be made of material chosen independently in the non-limiting list given below;
a semiconductor such as Ge, SiGe, Si,
a compound semiconductor such as GaAs, GaN, InSb, InP, etc.
   Furthermore, each of these layers may be strained if desired (i.e., a tensile and/or compressive strain). Each of these layers may also include mono-crystalline materials with substantially identical crystalline orientations.

In order to obtain a SOI-type structure according to the invention, a second working layer 104 having a crystalline orientation which is different from the crystalline orientation of the working layer 103 is formed or otherwise provided on top of the intermediate structure 100 (FIG. 2B). Therefore, in the hybrid structure 105 thus created, the second working layer 104 is in contact with the first working layer 103 and extends above it.

According to the invention, the respective crystalline orientations of both the first and second working layers are chosen so as to optimize the mobility of the carriers which will be provided by these respective layers. As a non-limiting example, the first working layer 103 may be made of a (1,0,0) crystal in silicon and the second working layer 104 in a (1,1,0) crystal in silicon. Such an arrangement makes it possible to obtain a SOI-type multilayer structure in which the first working layer is very well adapted for the manufacturing of NMOS type transistors while the second working layer is very well adapted to the manufacturing of PMOS type transistors. As a further non-limiting example, the first working layer 103 can be made of a (1,0,0) crystal in silicon which is under tensile strain while the second working layer 104 is a (1,1,0) crystal in silicon which is under compressive strain.

The method of providing the second working layer on top of the intermediate structure can be implemented in several ways know by the one skilled in the art. As an example, it may be formed by an epitaxial growth using well known techniques such as CVD (for Chemical Vapor Deposition) or MBE (for Molecular Beam epitaxy) techniques. However, according to a preferred method of the invention, the SOI-type multilayer structure is generally manufactured using a layer transfer technique which is especially described in the document entitled “Silicon On Insulator Technology: Materials to VLSI, 2^{nd} edition” from Jean Pierre Colinge (Kluwer Academic Publishers). In this regard, a detailed example of such a manufacturing method is shown in FIG. 3 for manufacturing the intermediate structure 100. FIG. 4 describes detailed steps of such a method that can be used to manufacture the hybrid SOI-type multilayer structure 105, it being understood that the method presented in FIG. 4 starts from the intermediate structure 100.

As can be seen in FIG. 3A, in order to manufacture the intermediate structure, one starts with a support layer 101 which can be made of a material such as silicon, sapphire, diamond, etc., and which supports the insulator 102 over its entire surface (FIG. 3A). Preferably, the insulator 102 may be a silicon oxide, also called silica or SiO2, because it is able to exhibit good adhesion with the support layer 101. The insulator layer may also be composed of multiple layers of different distinct compositions. The silicon oxide layer is preferably deposited over the surface of the support layer 101 by thermal oxidation although it can instead be provided by other known techniques.

In FIG. 3B, a source substrate 107 having for example a (1,0,0) crystalline orientation is considered. Atomic species are implanted in this source substrate in order to form an embrittlement zone 106 at a predefined depth within the source substrate. As can be seen in this figure, such an implantation defines within the source substrate 107 a layer which will correspond to the first working layer 103 of the final SOI-type structure which is to be obtained. Thereafter, the source substrate 107 is brought into intimate contact with the silicon oxide 102 supported by layer 101 and both of these layers are bonded advantageously by molecular adhesion.

This bonding technique, as well as variants thereof, are described for example in the document entitled “Semiconductor Wafer Bonding” (Science and Technology, Interscience Technology) by Q. Y. Tong, U. Gösele and Wiley. If necessary, bonding is accompanied by an appropriate prior treatment of at least one of the respective surfaces to be bonded. As a non-limiting example, such a treatment can be performed in order to allow the bond to be strengthened.

Once bonding has been performed as shown in FIG. 3C, the layer part 107′ of the source substrate 107 which does not correspond to the working layer 103 is removed by splitting or detachment. To that effect, energy is supplied in particular to the source substrate so that, due to mechanical constraints, the layer part 107′ detaches from the source substrate 107 at the depth defined by the embrittlement zone which is weakened. Typically, the supply of energy can be performed with a heat treatment or with a mechanical treatment known by the skilled artisan. If desired, although not preferred, layer part 107′ can be removed by other techniques. In any case, FIG. 3D shows the resulting intermediate structure 100 composed successively, from top to bottom, of the (1,0,0) crystalline orientation working layer 103, the silicon oxide 102 and the support layer 101.

Referring now to FIG. 4, a method is illustrated for forming on top of the intermediate structure 100 a second working layer 104 having a crystalline orientation which is different from the crystalline orientation of the (1,0,0) working layer 103 of the intermediate structure. According to the example mentioned above, the second working layer 104 may have a (1,1,0) crystalline orientation. As a preliminary step of this method, atomic species are implanted in a (1,1,0) source substrate 109 (FIG. 4B). Once again, an embrittlement zone 108 is thus created at a predetermined depth within the source substrate 109, which can be different from the one mentioned previously, and which defines within the second source substrate 109 a layer corresponding to the second working layer 104. Then, the surface of the second source substrate corresponding to a surface of the second working layer 104 is brought into intimate contact with the surface of the first working layer 103 extending on top of the intermediate structure 100, and bonding is performed (FIG. 4C), if desired, with a heat treatment. Finally, as shown in FIG. 4D, the layer part 109′ of the second source substrate 109 which does not correspond to the second working layer 104 is removed preferably by splitting or detaching the source substrate 109 at the embrittlement zone 108 to obtain the hybrid SOI-type multilayer structure 105 of the invention.

Naturally, other steps in the methods described above may be included in the method of the invention. In particular, one may integrate a step of treating the surface of the second working layer 104 after it has been bonded to the intermediate structure 100, and/or treating the surface of the intermediate structure 100 before forming on top of it the second working layer 104. Indeed, after a splitting or detaching step, the surface of the working layer thus formed may include a little surface roughness which can be cured if desired by conducting a thermal treatment such as an annealing treatment.

Further steps could also be included after having created the hybrid SOI-type multilayer structure 105. As an example, a further step of removing a desired portion of the second working layer 104 can be added. FIG. 5 shows such a kind of removal, but performed over the entire depth of the layer 104 in question. Therefore, observed from the top, the surface of the hybrid SOI structure 105 shows regions where the apparent layer is the first working layer and regions where the apparent layer is the second working layer. This makes it possible to access to both of them in the case for example of fabricating transistors of two different types.

In FIG. 5 however, such a kind of hybrid SOI structure is seen in cross-section. A dotted line I clearly distinguishes two stacking areas 200 and 201. One stacking area corresponds to an elementary layer pattern comprising either the support layer 101, the insulating layer 102 and the first working layer, or the support layer, the insulating layer, the first working layer and the second working layer 104. Typically, removing a desired portion from the second working layer as illustrated in FIG. 5 can be performed by selective chemical etching, but the skilled artisan will be able to choose any other techniques known in the state of the art which will be best appropriate for any particular case. Further, it may be also understood that, if desired, the overall thickness of the working layers in a stacking area (for example, the thickness of the working layer 103 in the stacking area 201) can be made equal to the overall thickness of the working layers in another staking area (in the above example, the added thickness of the first and the second working layer 103 and 104 in the stacking area 201), so that the top surface of the structure 105 is substantially even.

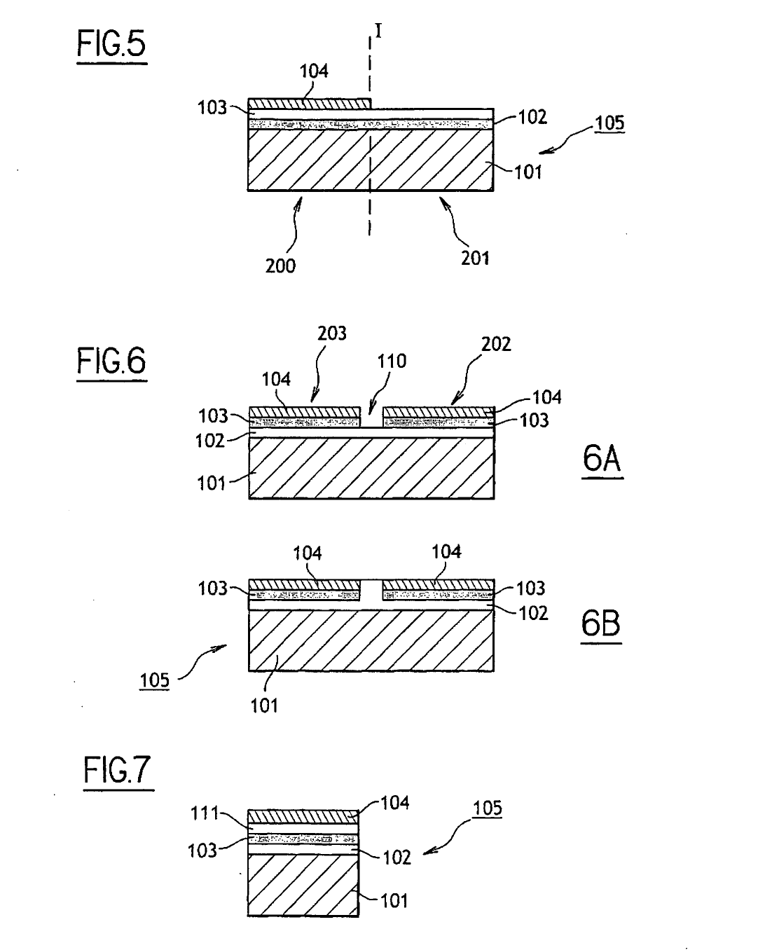

FIG. 6 shows another additional step which can be implemented in order to electrically isolate the working layer(s) of a stacking area 202 from the working layer(s) of adjacent stacking areas. To that effect, a trench 100 is formed through the entire depth of the working layers of the stacking area which has to be isolated (FIG. 6A). As can be understood, such a trench is also formed so as to surround the working layer(s) of the stacking area 202, and this along its (or their) depth. The trench 110 is then filled with an electrical insulator (FIG. 6B), preferably of the same insulator as the one 102 used to electrically isolate the working layers from the support layer 101, e.g., an SiO2 layer. Consequently, the trench may be in the form of shallow trench isolation (STI) to achieve this result.

A particular advantage of such a further step resides in the fact that a transistor fabricated in a stacking area is electrically isolated from components, such as other transistors, fabricated in other stacking areas and more particularly from components fabricated in adjacent stacking areas. It is to be noted too that in a stacking area thus manufactured, the first working layer 103 extending just above the second working layer 104 may be used to bias the second working layer 104. To do so, at least a via may be provided to contact specifically the first working layer 103 to an electrical source generating the bias voltage or the bias current. In this manner, the threshold voltage of the second working layer 104 may be modified as desired and in a very convenient way. In particular, such a solution may also help conserve layout area.

Another embodiment of the invention is illustrated in FIG. 7. As can be seen, the hybrid SOI-type structure comprises an additional insulating layer 111 which is interposed between the first and second working layers 103 and 104 having respectively different crystalline orientations. An advantage of such a structure resides in the fact that, the working layers of a stacking area being electrically isolated one another, a component, such as transistor, which may be manufactured from the second working layer 104 is not subject to electrical perturbations which would be present in the first working layer 103. To this end, the method of manufacturing the hybrid SOI-type structure proposed by the invention can be completed by an additional step of forming the second insulating layer 111.

As a non-limiting example, this insulating layer 111 may be obtained by oxide deposition on the top surface of the first working layer before having transferred the second working layer to the structure. As another example, the insulating layer 111 may be first deposited on the second source substrate 107 represented in FIG. 3B. Then implantation of atomic species is performed through such a temporary structure in order to create a weakened zone, namely an embrittlement zone, within the second source substrate 107. The free surface of the insulating layer 111 is brought into intimate contact with the top surface of the first working layer 103 and bonded with one of the techniques previously mentioned.

Naturally, the scope of the invention is not limited to the various preferred embodiments described above as examples. In particular, a working layer of the SOI-type multilayer structure of the invention may have a (1,1,1) crystalline orientation to manufacture for example a PMOS transistor. Such as structure can easily be made using the methods disclosed herein.

What is claimed is:

1. A silicon-on-insulator-type multilayer structure comprising a support layer, at least two working layers having different crystalline orientations, and an insulating layer for electrically isolating the support layer from the working layers.

2. The multilayer structure of claim 1, wherein only two working layers are present and these are superimposed in the structure.

3. The multilayer structure of claim 1, wherein the working layers comprise silicon.

4. The multilayer structure of claim 1, wherein one working layer comprises a (1,0,0) crystal adapted for the manufacturing of NMOS type transistors and another working layer comprises a (1,1,0) crystal adapted for the manufacturing of PMOS type transistors.

5. The multilayer structure of claim 1, which further comprises a plurality of different stacking areas, with each stacking area comprising:
a first composition of a support layer, an insulator layer; and a first working layer having an exposed top surface, or
a second composition of a support layer, an insulator layer; a first working layer and a second working layer having an exposed top surface,
so that within each stacking area either the first or second working layer has an exposed top surface.

6. The multilayer structure of claim 5, wherein the first working layer has a thickness in the first composition that is equal to the total thickness of the first and second working layers of the second composition so that the structure has a uniform top surface.

7. The multilayer structure of claim 5, wherein the working layers of one stacking area are electrically isolated from the working layers of adjacent stacking areas.

8. The multilayer structure of claim 7, wherein the isolation is provided by Shallow Trench Isolation.

9. The multilayer structure of claim 1, wherein at least one working layer is mono-crystalline.

10. The multilayer structure of claim 1, wherein at least one working layer comprises a strained semiconductor material.

11. The multilayer structure of claim 1, wherein at least one working layer includes tensile or compressive strain.

12. The multilayer structure of claim 1, which further comprises an additional insulating layer located between the two working layers so that the working layers are electrically isolated from each other.

13. The multilayer structure of claim 12, wherein each of the insulating layers comprises an oxide.

14. A process for manufacturing a silicon-on-insulator-type multilayer structure that includes a support layer, at least two working layers having different crystalline orientations, and an insulating layer for electrically isolating the support layer from the working layers, which method comprises:
providing an intermediate structure that includes the support layer, the insulating layer and a first working layer having an exposed surface; and
subsequently associating the second working layer upon the exposed surface of the first working layer of the intermediate structure to form the silicon-on-insulator-type multilayer structure.

15. The process of claim 14, which further comprises:
providing the intermediate structure by:
providing the insulating layer upon the support layer,
implanting atomic species in a first source substrate to form an embrittlement zone which defines within the first source substrate a layer corresponding to the first working layer,
bonding the first source substrate to the insulating layer;
splitting the first source substrate at the embrittlement zone so that the first working layer is transferred to the intermediate structure, and
providing the second working layer by:
implanting species in a second source substrate to form an embrittlement zone which defines within the second source substrate a layer corresponding to the second working layer,
bonding the second source substrate to the first working layer, and
splitting the second source substrate at the embrittlement zone to transfer the second working layer to the SOI-type multilayer structure.

16. The process of claim 14, which further comprises treating the exposed surface of the first working layer of the intermediate structure before forming the second working layer thereon.

17. The process of claim 14, which further comprises selectively removing desired portions of the second working layer to form two types of layer stacking:
a first layer stacking comprising a support layer, an insulator layer; and a first working layer having an exposed top surface, or
a second layer stacking comprising a support layer, an insulator layer; a first working layer and a second working layer having an exposed top surface,
so that within each stacking area either the first or second working layer has an exposed top surface.

18. The process of claim 14, which further comprises selectively forming desired trenches which expose the insulating layer.

19. The process of claim 18, which further comprises filling the trenches with an insulating material.

20. The process of claim 14, wherein the working layers are semiconductor layers.

21. The process of claim 14, wherein the working layers are mono-crystalline layers.

22. The process of claim 14, wherein one of the working layers is made of a (1,0,0) crystal and another of the working layers is made of a (1,1,0) crystal.

23. The process of claim 14, wherein at least one working layer is strained with tensile or compressive strain.

24. The process of claim 14, which further comprises forming an additional insulating layer on one of the working layers before associating the second working layer upon the first working layer.

25. The process of claim 24 wherein the insulating layers are each made of an oxide.
